(19) United States
(12) Patent Application Publication
(10) Pub. No.: US 2010/0044554 A1
(43) Pub. Date: Feb. 25, 2010

(54) Timebase Circuit Arrangements

(76) Inventor: Jos Duivenvoorden, Trent River (CA)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 12/543,581

(22) Filed: Aug. 19, 2009

(30) Foreign Application Priority Data
Aug. 19, 2008 (EP) 08014720.0

(51) Int. Cl. H01L 31/00

(52) U.S. Cl. 250/214.1

(57) ABSTRACT

A timebase is provided by a circuit including an optical source emitting a light beam which is detected and integrated by an optical detector/integrator to give an output when the integrated value reaches a preset value. The optical source is a laser or LED. The optical detector/integrator is a photon counter.

### CROSS REFERENCE TO RELATED APPLICATIONS

This application claims priority of European Patent Office Application No. 08014720.0 EP filed Aug. 19, 2008, which is incorporated by reference herein in its entirety.

### FIELD OF INVENTION

This invention relates to timebase circuits for use in electronic apparatus. The invention is of particular usefulness in the field of radar-based measurement systems, such as level measurement in industrial process control, but may equally be of utility in other applications that need a very accurate timebase, such as ultrasonic, TDR (Time Domain Reflectometry) or oscilloscope measurement equipment.

### SUMMARY OF INVENTION

Radar-based pulse echo measurement systems operate essentially by measuring time of flight of a pulse. Conventional systems are designed to produce accuracies of the order of a few millimetres and to deal with levels which change relatively slowly. There is a need in the industry to provide sub-millimetre accuracy, and to cope with more rapidly changing levels.

Current systems which attempt to address these needs are experiencing timebase jitter which translates to inaccuracy from measurement shot to measurement shot. The accuracy can be improved somewhat by averaging over a number of measurements. However, this involves a relatively long time settlement, and a slow response to rapidly changing tank levels.

The present invention, from one aspect, provides a timebase generating circuit comprising an optical source for producing a light beam of constant intensity, an optical detector, and an integrator connected to integrate the light detected by the optical detector and to provide a timing output when a preset integrated value is achieved.

The invention is based upon realising the timebase in the optical domain. This allows use of frequencies which are capable of giving a timebase resolution equivalent to 0.1 mm of level, and a high degree of immunity to crosstalk from adjacent circuits.

Preferably, the optical detector and the integrator are formed by a photon counter. This provides an off-the-shelf approach to forming both elements in a single item.

Alternatively, the optical detector may comprise a light sensitive resistor.

The light source is preferably a coherent light source, such as a laser, preferably is a resonant laser; this minimises temperature effects. Alternatively the light source may be a light-emitting diode.

The invention also provides a radar-based pulse echo level measurement system including the timebase circuit defined above. Such a system may have sub-millimetre accuracy.

From another aspect, the invention provides a method of generating timebase signals, comprising generating a constant intensity light beam, detecting the light beam, integrating the detected signal, and generating a timing output when a preset integrated value is achieved.

The detection and integration are preferably performed as a single step by photon counting.

### BRIEF DESCRIPTION OF THE DRAWINGS

An embodiment of the invention will now be described, by way of example only, with reference to the drawing.

FIG. 1 is a schematic block diagram illustrating one form of the invention.

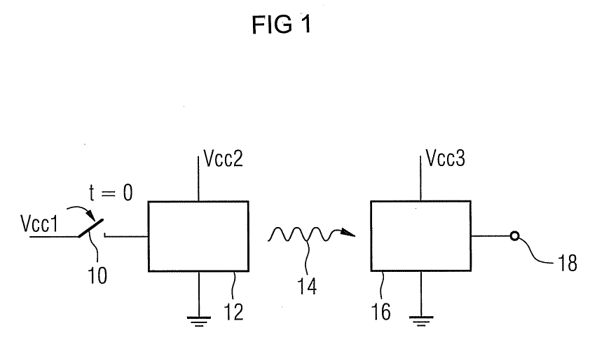

### DETAILED DESCRIPTION OF INVENTION

The problem of timebase accuracy outlined above can be addressed by using a higher timebase frequency. For example, for a timebase resolution equivalent to 0.1 mm the wavelength in vacuum should be c/f (speed of light divided by frequency), which implies a frequency of 3 THz (3⁸/1⁻⁴). In a medium other than vacuum, the frequency changes with the square root of the dielectric constant of the medium. The invention is based upon using light to provide the timebase.

Referring to the drawing, the timebase is started at t=0 by a trigger such as switch 10 applying a controlled voltage Vcc1 to an optical source 12 to produce a light beam 14. the light beam 14 is detected and integrated by an optical detector/integrator 16. When the integrated value reaches a preset level, an output 18 is produced, suitably in the form of a clock pulse. This provides a highly accurate timebase suitable for level detecting radar, or other applications requiring a similar degree of accuracy.

The light source 12 is typically either a light-emitting diode or a coherent light source such as a laser. A preferred arrangement is to use a resonant laser, in which the frequency is determined by the cavity dimensions and is highly independent of temperature.

The light source may operate in the range from infrared to ultraviolet. For use in radar based pulse echo systems it is preferred to use high frequency light with a frequency above 300 GHz.

The light beam 14 can be guided or unguided; in other words it may be transmitted via a guide such as an optical fibre or fibre optic bundle, or may pass through free space.

The optical detector/integrator 16 in one form of the invention comprises a photon counter. Photon counters are well known in the art and are commercially available. The use of a photon counter is advantageous in that accumulating the count of detected photons provides integration directly, the accumulated count forming a measure of evolved time.

However, other forms of optical detector/integrator may be used. For example, a light-influenced resistor or a photodiode may be used, in conjunction with an integrating component such as a capacitor.

The invention thus provides a simple manner of producing a high quality timebase of a frequency suitable for use in radar-based level measurement systems. Forming the timebase in the optical domain provides a high degree of immunity from crosstalk and other interference.

1.-9. (canceled)

10. A timebase generating circuit, comprising:
an optical source for producing a light beam of constant intensity;
an optical detector; and
an integrator connected to integrate the light detected by the optical detector and to provide a timing output when a preset integrated value is achieved.

11. The circuit as claimed in claim 10, wherein the optical detector and the integrator are formed by a photon counter.

12. The circuit as claimed in claim 10, wherein the optical detector comprises a light sensitive resistor.

13. The circuit as claimed in claim 10, wherein the light source is a laser.

14. The circuit as claimed in claim 13, wherein the laser is a resonant laser.

15. The circuit as claimed in claim 10, wherein the light source is a light-emitting diode.

16. A radar-based pulse echo level measurement system, comprising:
a timebase generating circuit, comprising:
an optical source for producing a light beam of constant intensity,
an optical detector, and
an integrator connected to integrate the light detected by the optical detector and to provide a timing output when a preset integrated value is achieved.

17. The system as claimed in claim 16, wherein the optical detector and the integrator are formed by a photon counter.

18. The system as claimed in claim 16, wherein the optical detector comprises a light sensitive resistor.

19. The system as claimed in claim 16, wherein the light source is a laser.

20. The system as claimed in claim 19, wherein the laser is a resonant laser.

21. The system as claimed in claim 16, wherein the light source is a light-emitting diode.

22. A method of generating timebase signals, comprising:
generating a constant intensity light beam;
detecting the light beam;
integrating the detected signal; and
generating a timing output when a preset integrated value is achieved.

23. The method of claim 22, wherein the detecting and integrating are performed as a single step by photon counting.
